(19) United States
(12) Patent Application Publication
(10) Pub. No.: US 2024/0355956 A1
(43) Pub. Date: Oct. 24, 2024

(54) METHOD OF FORMING POROUS III-NITRIDE MATERIAL

(71) Applicant: PORO TECHNOLOGIES LTD, Cambridge, Cambridgeshire (GB)

(72) Inventors: Yingjun LIU, Cambridge, Cambridgeshire (GB); Tongtong ZHU, Cambridge, Cambridgeshire (GB)

(21) Appl. No.: 18/686,806

(22) PCT Filed: Aug. 26, 2022
(86) PCT No.: PCT/GB2022/052202

§ 371 Date: Feb. 26, 2024

(30) Foreign Application Priority Data
Aug. 27, 2021 (GB) 2112318.7
Aug. 25, 2022 (TW) 111132116

(51) Int. Cl. H01L 33/00; H01L 33/24; H01L 33/32

(52) U.S. Cl. CPC H01L 33/0075; H01L 33/24; H01L 33/325

(57) ABSTRACT

A method for forming porous Ill-nitride material comprises the steps of exposing a Ill-nitride material to a gas, coupling the Ill-nitride material to one terminal of a power supply, and coupling an electrode to another terminal of the power supply, and via the gas forming a circuit. The method comprises the step of energising the circuit to etch a plurality of pores in the Ill-nitride material and thereby form a porous Ill-nitride material. Pores are preferably formed in Ill-nitride material having a charge carrier density of greater than 1×10¹⁷ cm³. A semiconductor structure, a template for semiconductor overgrowth, and a semiconductor device comprising porous Ill-nitride material formed by the method are also provided.

The invention relates to a method for forming porous Ill-nitride material, and to porous III-nitride material and semiconductor devices made therefrom.

### BACKGROUND

“III-V” semiconductors include binary, ternary and quaternary alloys of Group III elements, such as Ga, Al and In, with Group V elements, such as N, P, As and Sb), and are of great interest for a number of applications, including optoelectronics.

III-V semiconductor materials are of particular interest for semiconductor device design, in particular the family of Ill-nitride semiconductor materials.

“III-V” semiconductors include binary, ternary and quaternary alloys of Group III elements, such as Ga, Al and In, with Group V elements, such as N, P, As and Sb), and are of great interest for a number of applications, including optoelectronics.

Of particular interest is the class of semiconductor materials known as “III-nitride” materials, which includes gallium nitride (GaN), indium nitride (InN) and aluminium nitride (AlN), along with their ternary and quaternary alloys (Al,In)GaN. Different crystal orientations may be used in the present invention, such as polar c-plane, non-polar and semi-polar orientations. There are two primary non-polar orientations, a-plane (11-20) and m-plane (1-100). For semi-polar, there are (11-22), {2021} which is a family of crystal planes. III-nitride materials have not only achieved commercial success in solid-state lighting and power electronics, but also exhibit particular advantages for quantum light sources and light-matter interaction.

While a variety of III-nitride materials are commercially interesting, Gallium nitride (GaN) is widely regarded as one of the most important new semiconductor materials, and is of particular interest for a number of applications.

It is known that the introduction of pores into bulk III-nitrides, such as GaN can profoundly affect its material properties (optical, mechanical, electrical, and thermal, etc.). The possibility of tuning a wide range of material properties of GaN and III-nitrides semiconductors by altering its porosity therefore makes porous GaN of great interest for optoelectronic applications.

Prior art methods for forming porous III-nitride material have focused on electrochemical (EC) etching in liquid electrolytes such as oxalic acid, and on photo-electrochemical (PEC) etching, where the III-nitride material is illuminated with UV light during electrochemical etching. Examples of such techniques for porosifying III-nitride material are disclosed, for example, in U.S. Pat. No. 9,206,524B2, and in international patent applications PCT/GB2017/052895 (published as WO2019/063957) and PCT/GB2019/050213 (published as WO2019/145728).

### SUMMARY OF INVENTION

The invention provides a method of forming porous III-nitride material, as defined in the appended independent claims to which reference should now be made. Preferred or advantageous features of the invention are set out in dependent subclaims.

According to a first aspect of the invention there is provided a method for forming porous III-nitride material. The method comprises the steps of exposing a III-nitride material to a gas, coupling the III-nitride material to one terminal of a power supply and coupling an electrode to another terminal of the power supply. A circuit is formed between the III-nitride material and the electrode via the gas, and the circuit is energised to etch a plurality of pores in the III-nitride material and thereby form a porous III-nitride material.

The III-nitride material is preferably non-porous III-nitride material prior to the circuit being energised, so the method may alternatively be termed a method for porosifying III-nitride material.

Energising the circuit preferably creates a gas plasma, consisting of a gas of ions through which current can flow between the III-nitride material and the electrode to complete the circuit.

The pores may be etched in the III-nitride material by plasma electrolytic etching. The pores may be etched in the III-nitride material by plasma electrolytic oxidation or reduction (or redox reactions).

The method may comprise the steps of exposing a semiconductor structure comprising a first region of III-nitride material to a gas, coupling the semiconductor structure to one terminal of a power supply and coupling an electrode to another terminal of the power supply. A circuit is formed between the first region of III-nitride material and the electrode via the gas, and the circuit is energised to etch a plurality of pores in the first region of III-nitride material and thereby form a porous region of III-nitride material.

The first region of III-nitride material may preferably have a charge carrier density of greater than 1×10¹⁷ cm⁻³. The first region may be formed from doped III-nitride semiconductor material with a charge carrier density of greater than 5×10¹⁷ cm⁻³, or 1×10¹⁸ cm⁻³, or 5×10¹⁸ cm⁻³, or 1×10¹⁹ cm⁻³.

When the circuit is energised, pores are formed selectively in regions of the semiconductor structure with a charge carrier density above a threshold. For example, pores may be formed selectively in regions of the semiconductor structure with a charge carrier density above a threshold of 1×10¹⁷ cm⁻³. As the first region of III-nitride preferably has a charge carrier density of greater than 1×10¹⁷ cm⁻³, pores are formed in the first region.

Unlike the prior art methods for forming porous III-nitride material, in the method of the present invention the III-nitride material is not exposed to an electrolyte. In the prior art, liquid electrolytes have been a vital component for electrochemical or photoelectrochemical etching, but in the method of the present invention the III-nitride material is not in contact with a liquid electrolyte.

As no liquid electrolyte is used in the plasma electrolytic etching process of the present invention, the present invention advantageously eliminates the requirement for costly, time-consuming and polluting cleaning steps after porosification. The gas-based method of the present invention may also be significantly better than liquid-electrolyte processes for the purposes of mass-production of porous wafers and integration with automated wafer-handling apparatuses.

The gas may be a pure gas, or the gas may be a mixture of gases of one of more elements or compounds.

In preferred embodiments, the gas may comprise H₂, O₂, N₂, Ar, CO₂, CH₄, H₂O, H₂O₂, O₃, CO, SO₂, SO₃, NO₂, NO, H₂S, NH₃, Cl₂, Br₂, F₂, I₂, HCl, HBr, or HF, or a mixture of two or more of H₂, O₂, N₂, Ar, CO₂, CH₄, H₂O, H₂O₂, O₃, CO, SO₂, SO₃, NO₂, NO, H₂S, NH₃, Cl₂, Br₂, F₂, I₂, HCl, HBr, or HF. The gas may be air.

The composition of the gas may remain the same throughout the etching process. Alternatively, the composition of the gas may be varied during etching of the pores in the III-nitride material.

The method may further comprise the step of varying the composition of the gas. The method may comprise the step of varying the composition of the gas as a function of time to generate a porosity profile in the III-nitride material. The porosity profile may comprise variations in pore morphology, pore size and percentage porosity.

The method may comprise the step of varying the composition of the gas while the circuit is energised, or alternatively the steps of de-energising the circuit, altering the composition of the gas, and re-energising the circuit.

Preferably the method may be carried out with the III-nitride material and the electrode in a chamber in which gas may be sealed, or through which gas may be pumped. The gas may be pumped continuously through the chamber. The composition of the gas may thus be altered at any point during the etching process by changing the composition of the gas fed into the container.

The gas may comprise a vapour of one or more inorganic salts. For example, the gas may comprise a vapour of one or more of LiF, NaF, NaCl, LiCl, KCl, LiBr, LiNO₃, NaNO₃, KNO₃, CaCl₂, SnCl₂, ZnCl₂, ZnBr₂, CuCl₂, AlCl₃, FeCl₃, TiCl₄, ZrCl₄, PCI₃, PCI₅, NH₄Cl, NH₄NO₃.

The gas may comprise a vapour of one or more metals. For example, the gas may comprise a vapour of one or more of Li, Na, K, Hg, Ga, In, Al, or Pb.

The gas may comprise a vapour of one or more acids, preferably one or more acids of low boiling point, for example boiling points <350° C. at 1 atm. For example, the gas may comprise a vapour of one or more of formic acid, acetic acid, propionic acid, butyric acid, citric acid, oxalic acid, HPO3.

The vapour of one or more inorganic salts and/or the vapour of one or more metals and/or the vapour of one or more acids may be introduced into the gas in addition to, or to replace, the gases and mixtures of gases set out above. For example the vapour of one or more inorganic salts and/or the vapour of one or more metals and/or one or more acids may be introduced into the gas at a predetermined time, and/or for a predetermined duration of time, during the porosification process.

The method may comprise the step of exposing the III-nitride material to a vapour of one or more inorganic salts, and/or a vapour of one or more metals, and/or the vapour of one or more acids, to generate a porosity profile. The vapour of one or more inorganic salts, and/or the vapour of one or more metals, and/or the vapour of one or more acids, may be introduced into the gas for a predetermined period during etching of the pores, such that the composition of the gas is altered to contain these constituents for the predetermined period. Introducing certain constituents into the gas during the process may advantageously allow the porosity profile of the III-nitride material to be controlled as the process of etching the pores proceeds.

The method may comprise the step of applying a voltage in the range between 0.1 V and 500 kV, or between 0.1 V and 250 kV, or between 0.1 V and 150 kV. In order to complete the circuit, the voltage is applied between the electrode and the III-nitride material, so that the circuit is completed by ions in the gas flowing between the electrode and the III-nitride material.

The method may comprise the step of applying a voltage in the range between 0.1 V and 10000 V, or between 0.5 V and 5000 V, or between 1 V and 1000 V. In order to complete the circuit, the voltage is applied between the electrode and the III-nitride material, so that the circuit is completed by ions in the gas flowing between the electrode and the III-nitride material.

The method may comprise the step of varying the voltage as a function of time. Varying the voltage across the circuit during the process may advantageously allow the porosity profile of the III-nitride material to be controlled as the process of etching the pores proceeds.

In some embodiments, the etching may comprise applying a first voltage V₁ for a first time duration t_{V1}; and applying a second Voltage V₂ for a second time duration t_{V2}.

Alternatively the voltage may be swept between a first voltage V₁ and a second Voltage V₂ over a predetermined period of time. For example the voltage may be ramped from the first voltage to the second voltage.

The amplitude of the voltage may in some embodiments increase from about 1 volt to a maximum of up to 500,000 volts over the predetermined period of time, preferably from about 1 volt to a maximum of up to 250,000 volts or from about 1 volt to a maximum of up to 150,000 volts or 125,000 volts.

The amplitude of the voltage may in some embodiments increase from about 1 volt to a maximum of up to 10000 volts over the predetermined period of time, preferably from about 1 volt to a maximum of up to 2000 volts or from about 1 volt to a maximum of up to 1000 volts or 500 volts.

The method may comprise the step of applying a voltage which exceeds a first breakdown voltage. The first breakdown voltage may typically be less than 10 kV, or less than 5 kV, or preferably less than 1 kV.

When the voltage between the electrode and the III-nitride material is greater than the first breakdown voltage, the gas breaks down to form an electrically conductive plasma of ions.

The method may comprise the step of applying a voltage which exceeds a second breakdown voltage. The second breakdown voltage may typically be greater than 10 kV, or greater than 50 kV, or greater than 75 kV, or greater than 100 kV.

When the voltage between the electrode and the III-nitride material exceeds the second breakdown voltage, the III-nitride material begins to break down, and the porosification process takes place.

The voltage may be applied as a sequence of voltage pulses, optionally a sequence of voltage pulses of alternating polarity, for a predetermined period of time. In some preferred embodiments, the voltage pulses have a pulse repetition frequency of between 0.1 and 20 KHz, preferably between 1.5 and 15, or between 2 and 10 KHz.

The III-nitride material may be coupled to the either negative terminal or the positive terminal of the power supply.

The method may optionally comprise the step of varying the pressure of the gas while the pores are etched. Preferably the pressure of the gas may be varied while the circuit is energised. Varying the gas pressure during the process may advantageously allow the porosity profile of the III-nitride material to be controlled as the process of etching the pores proceeds.

The method may comprise the step of sweeping the pressure of the gas from a first gas pressure P₁ to a second gas pressure P₂ pressure. For example, the pressure of the gas may be swept, or ramped, between 0 bar and 20 bar, or between 1 bar and 15 bar, or between 1 bar and 10 bar, while the circuit is energised.

The method may comprise the step of applying a first gas pressure P₁ for a first time duration t_{P1}; and applying a second gas pressure P₂ for a second time duration t_{P2}.

The method may optionally comprise the step of varying a temperature of the gas and/or the III-nitride material. The temperature may preferably be varied while the circuit is energised. Varying the temperature as a function of time during the process may advantageously allow the porosity profile of the III-nitride material to be controlled as the process of etching the pores proceeds.

The method may comprise the step of applying a first gas temperature T₁ for a first time duration t_{T1}; and applying a second gas pressure T₂ for a second time duration t_{P2}.

Alternatively the temperature of the gas is swept between a first temperature T₁ and a second temperature T₂ over a predetermined period of time.

The method may comprise the step of exposing the III-nitride material to the gas at a temperature in the range between −50° C. and 1100° C., or between 0° C. and 1000° C., or between 50° C. and 800° C., or between 100° C. and 500° C.

The method may comprise the step of varying a temperature of the gas and the III-nitride material between a first temperature T₁ and a second temperature T₂ while the circuit is energised.

The method may comprise the step of varying the separation, or distance, between the III-nitride material (or the semiconductor structure) and the electrode while the circuit is energised. The distance between the III-nitride material (or the semiconductor structure) and the electrode while the circuit is energised may be zero (so that the electrode is in contact with the semiconductor structure being porosified), or it may be greater than zero (so that there is a separation between the electrode and the semiconductor structure being porosified).

The method may comprise the step of forming a non-uniform porosity profile in the III-nitride material by varying or adjusting one or more of: the gas composition; the voltage applied between the electrode and the III-nitride material; the temperature of the gas; and the pressure of the gas. These parameters may be varied while the circuit is energised, or alternatively the circuit may be temporarily de-energised, and then re-energised once the parameter has been adjusted.

The porosity profile may comprise variations in pore morphology, pore size and percentage porosity. By varying or adjusting one or more of: the gas composition; the voltage applied between the electrode and the III-nitride material; the distance between the electrode and the III-nitride material; the temperature of the gas; and the pressure of the gas, the formation of pores in the porous III-nitride material may advantageously be controlled to give a desired porosity profile in the resulting porous III-nitride material.

The III-nitride material is preferably selected from the list consisting of: GaN, AlGaN, InGaN, InAlN, AlInGaN, and AlN.

The III-nitride material may preferably be disposed on a substrate comprising Sapphire, silicon, silicon carbide, β-Ga2O3 or bulk GaN. The III-nitride material to be porosified is preferably provided as a layer, or at least a region of a layer, of crystalline semiconductor material on the substrate. The substrate may prevent one side of the III-nitride material from coming into contact with the gas.

At least a first region of the III-nitride material preferably consists of n-type doped III-nitride material, which is preferably doped with one or more of silicon (Si), germanium (Ge) and oxygen (O).

The plurality of pores may be etched in a first region of the III-nitride material. The first region of III-nitride material has a charge carrier density of greater than 1×10¹⁷ cm⁻³. The first region may be formed from doped III-nitride semiconductor material with a charge carrier density of greater than 5×10¹⁷ cm⁻³, or 1×10¹⁸ cm⁻³, or 5×10¹⁸ cm⁻³, or 1×10¹⁹ cm⁻³.

Pores are formed selectively in doped portions of the III-nitride material, typically in doped portions of III-nitride material having charge carrier concentrations greater than 1×10¹⁷ cm⁻³.

The III-nitride material may additionally comprise a second portion having a charge carrier density of less than 1×10¹⁷ cm⁻³, in which no pores are formed when the circuit is energised.

When the circuit is energised, pores are formed in the first region of the III-nitride material so that the first region of the III-nitride material becomes a porous region of III-nitride material. The first region may have a thickness of at least 1 nm, preferably at least 10 nm, particularly preferably at least 50 nm. For example, the first region may have a thickness between 1 nm and 10000 nm.

The III-nitride material to be porosified may be part of a semiconductor structure. For example the semiconductor structure may comprise a plurality of layers of III-nitride material, including a first region of III-nitride material which will be porosified when the circuit is energised.

### First Region

The first region of the III-nitride material may be a first layer, such that the semiconductor structure comprises a porous layer of III-nitride material after the porosification process has taken place. Preferably the first region may be a layer of doped III-nitride material with a uniform charge carrier density, so that porosification turns the first region into a porous layer that is continuously porous, for example formed from a continuous layer of porous III-nitride material.

The semiconductor structure may comprise a plurality of first regions with a charge carrier density high enough to be porosified, and a plurality of second regions with a charge carrier density too low to be porosified. In a preferred embodiment, for example, the semiconductor structure may comprise a plurality of first layers having a charge carrier density of greater than 1×10¹⁷ cm⁻³, and a plurality of second layers having a charge carrier density of less than 1×10¹⁷ cm⁻³, such that after porosification the semiconductor structure contains a plurality of porous layers formed from the first layers and a plurality of non-porous second layers.

In a particularly preferred embodiment, the semiconductor structure comprises a stack of alternating first layers having a charge carrier density of greater than 1×10¹⁷ cm⁻³, and second layers having a charge carrier density of less than 1×10¹⁷ cm⁻³. After the circuit has been energised and pores have been formed in the first layers, the semiconductor structure thus comprises a stack of alternating porous and non-porous layers.

In some embodiments, the semiconductor structure comprises multiple first regions in which pores will be formed when the circuit is energised. Thus, rather than being a single porous layer of III-nitride material, the porous semiconductor structure may comprise multiple porous regions, for example a stack of layers of III-nitride material in which at least some layers are porous. The stack of porous layers may preferably be a stack of alternating porous and non-porous layers.

Alternatively after the porosification process the semiconductor structure may comprise a layer of III-nitride material that contains one or more porous regions formed from porous first regions, for example one or more porous regions in an otherwise non-porous layer of III-nitride material. In other words, the porous region need not be a continuous layer of porous material.

In preferred embodiments, the porous region, or porous layer, may have a lateral dimension (width or length) equivalent to that of the substrate on which the porous layer or region is grown. For example, conventional substrate wafer sizes may have a variety of sizes, such as 1 cm², or 2 inch, 4 inch, 6 inch, 8 inch, 12 inch, or 16 inch diameter. By patterning one or more layers and/or depositing regions of different charge carrier concentrations in the same layer, however, smaller porous regions can be formed that do not span the entire substrate. The lateral dimensions of the porous layer or region may therefore vary from around 1/10 of a pixel (for example 0.1 μm), up to the lateral dimensions of the substrate itself.

The III-nitride material may preferably be provided as a wafer with a diameter of 1 inch (2.54 cm), or 2 inches (5.08 cm), or 6 inches (15.24 cm), or 8 inches (20.36 cm), or 16 inches or larger.

Preferably the method may produce pores in the first region with an average pore size of greater than 1 nm, or 2 nm, or 10 nm, or 20 nm, and/or less than 50 nm, or 60 nm, or 70 nm.

The pore size and morphology, and the resulting percentage porosity of the first region, may advantageously be controlled by controlling the charge carrier concentration of the first region and controlling parameters including voltage magnitude, voltage control regime, gas composition, gas pressure and temperature during porosification.

Preferably, the method may porosify the first region such that it is microporous. That is, it has an average pore size of less than 2 nm. Alternatively, the method may porosify the first region such that it is mesoporous. That is, it has an average pore size between 2 nm and 50 nm. Alternatively, the method may porosify the first region such that it is macroporous. That is, it has an average pore size of greater than 50 nm.

The method may comprise the step of forming, over the porous III-nitride material: an n-type layer, a p-type layer, and InGaN/GaN active layers between the n-type layer and the p-type layer to form a light emitting diode (LED). The LED may be formed over the porous III-nitride material according to known semiconductor device fabrication techniques.

In some embodiments, the doped first region may be a surface layer of the semiconductor structure, so that the doped first region of III-nitride material is directly exposed to the gas while the circuit is energised. Pores may then be formed in the surface layer of the semiconductor structure.

In alternative embodiments, the doped first region of III-nitride material may be a sub-surface first region, which is not directly exposed to the gas while the circuit is energised. In such embodiments the semiconductor structure may comprise an electrically-insulating surface layer covering the first region.

### Sub-Surface First Region

In addition to the doped first region, the semiconductor structure may comprise a non-porous surface layer of III-nitride material positioned over the porous region, so that the surface layer covers the first region, and prevents it from contacting the gas. The first region may thus be a “sub-surface” first region. The surface layer may preferably be a non porous layer through which plasma electrolytic etching of the porous region takes place. The surface layer may preferably have a charge carrier density of less than 1×10¹⁷ cm⁻³, so that no pores are formed in the surface layer when the circuit is energised.

The semiconductor structure preferably comprises a surface layer, which may be termed a capping layer, of electrically-insulating material arranged over, or above, the first region of III-nitride material. In preferred embodiments, the capping layer may be a layer of undoped III-nitride material such as undoped GaN. As the capping layer is undoped, it has a charge carrier density of less than 1×10¹⁷ cm⁻³, so that no pores are formed in this layer when the circuit is energised.

The first region of III-nitride material is preferably arranged, or positioned, between a substrate and an electrically-insulating capping layer which covers the top surface of the first region.

As described in international patent application PCT/GB2017/052895 (published as WO2019/063957), etching may advantageously proceed through the undoped surface layer without damaging, or forming pores, in the surface layer. Thus the first region of III-nitride material may be porosified even if the first region is sub-surface, and not in direct contact with the gas. In a similar fashion, a plurality of sub-surface doped first regions or layers may be porosified using the method of the present invention.

The step of exposing the III-nitride material to the gas may comprise exposing the surface layer of III-nitride material to the gas, or alternatively contacting the surface layer with a gas. Preferably the upper, top, or outermost, surface of the surface layer is exposed to the gas. Particularly preferably only the surface layer is exposed to the gas.

The surface layer may cover only the upper surface of the sub-surface first region of III-nitride material. In other words, the sub-surface first region may be arranged below, or underneath, the surface layer, or the surface layer may be arranged over the sub-surface first region of III-nitride material. The side-walls, or edges, of the sub-surface first region of III-nitride material may be exposed, that is, not covered by the surface layer, or alternatively the side-walls, or edges, of the sub-surface first region of III-nitride material may be covered so that the side-walls are not exposed to the gas.

By controlling the charge carrier density of the surface layer, as well as the charge carrier density of the sub-surface first region of III-nitride material, the sub-surface first region of III-nitride material can advantageously be porosified through the surface layer without the surface layer itself being porosified. Particularly advantageously, the sub-surface first region of III-nitride material can be electrochemically porosified without the surface layer being damaged or roughened during the etching process. Thus, the method of the present invention may advantageously allow the selective porosification of a complex (eg. multi-layered) III-nitride structure without having to apply a protective electrically conductive layer, of SiO₂ for example, onto the surface layer. This may eliminate the need for the time-consuming and costly extra processing steps of applying, and subsequently removing, a protective top layer that are required by some prior art methods.

The surface layer may have a charge carrier density of at least 5×10¹⁴ cm⁻³, or 1×10¹⁵ cm⁻³, or 5×10¹⁵ cm⁻³, and/or less than 7×10¹⁵ cm⁻³, or 1×10¹⁶ cm⁻³, or 5×10¹⁶ cm⁻³, or 8×10¹⁶ cm⁻³, so that the surface layer is not porosified during etching.

The non-porous surface layer may preferably be one of GaN, InGaN, AlGaN, AlInGaN or AlN.

By controlling the charge carrier densities of the layers and/or regions of III-nitride material, and the contrast in charge carrier density between adjacent layers, it is possible to pre determine the regions of the semiconductor structure which will be porosified by plasma electrolytic etching.

The sub-surface structure may have a charge carrier density of at least 5×10¹⁷ cm⁻³, or at least 1×10¹⁸ cm⁻³, or at least 5×10¹⁸ cm⁻³, or at least 1×10¹⁹ cm⁻³, or at least 5×10¹⁹ cm⁻³, or at least 1×10²⁰ cm⁻³, and/or less than 1×10²¹ cm⁻³, or 5×10²¹ cm⁻³, or 1×10²² cm⁻³, if it is to be porosified.

Preferably the surface layer and the sub-surface first region comprise a III-nitride material selected from the list consisting of: GaN, AlGaN, InGaN, InAlN and AlInGaN. The surface layer and the sub-surface first region may be formed from the same III-nitride material, but with a different charge carrier density in each, or the layers/regions may be formed of different III-nitride materials.

Suitable III-nitride materials may for example have any polar crystal orientation or non-polar crystal orientation. Suitable III-nitride materials may have any crystal structure, for example a wurtzite or cubic structure, and any crystal orientation. For example, suitable III-nitride materials may include polar c-plane, non-polar a plane, or even cubic III-nitride materials.

The surface layer is preferably a continuous layer of III-nitride material. That is, the surface layer is preferably substantially free from holes or large-scale defects.

The thickness of the surface layer is preferably at least 1 nm, or 10 nm, or 100 nm, and/or less than 1 μm, or 5 μm, or 10 μm.

The thickness of the sub-surface first region, or sub-surface first layer, is preferably at least 1 nm, or 10 nm, or 100 nm, and/or less than 1 μm, or 5 μm, or 10 μm.

In a particularly preferred embodiment, the surface layer consists of GaN with a charge carrier density of between 1×10¹⁴ cm⁻³ and 1×10¹⁷ cm⁻³, and the sub-surface first region consists of n-type doped GaN with a charge carrier density greater than 5×10¹⁷ cm⁻³.

Preferably the charge carrier density in the sub-surface first region is at least 5 times, or 10 times, or 100 times, or 1000 times, or 10,000 times, or 100,000 times, or 1,000,000 times higher than the charge carrier density in the surface layer. Increased differences between the charge carrier densities of different layers, which may be thought of as increased “contrast” in charge carrier densities, may advantageously increase the selectivity of the etching process.

Preferably the threading dislocation density in both the surface layer and the sub-surface first region is between 1×10⁴ cm⁻² and 1×10¹⁰ cm⁻². Particularly preferably the threading dislocation density in both the surface layer and the sub-surface first region is substantially equal. Preferably the threading dislocation density in both the surface layer and the sub surface first region is at least 1×10⁴ cm⁻², 1×10⁵ cm⁻², 1×10⁶ cm⁻², 1×10⁷ cm⁻², or 1×10⁸ cm⁻² and/or less than 1×10⁹ cm⁻² or 1×10¹⁰ cm⁻². Typically, growers of semiconductor materials seek to minimise the threading dislocation density of the material in an effort to improve material quality. In the present invention, however, a sufficient threading dislocation density between the surface layer and the sub-surface first region may be required to allow etching to occur below the undoped surface layer. This may be due to increased charge carrier transport to the sub-surface first region.

In order to avoid damage to “undoped” surface layers, the creators of many prior art EC porosification methods have found it necessary to apply protective dielectric layers to the top surfaces of their samples.

The skilled person will appreciate that the term “undoped” is relatively imprecise in semiconductor technology, as practically speaking, all semiconductor material contains inherent impurities which can be thought of as “dopant” atoms. Different methods of semiconductor growth may produce different levels of impurity, and thus different inherent charge carrier concentrations. Where impurity levels are high, the resulting semiconductor material may have a charge carrier density of above 1×10¹⁷ cm⁻³, even though the layer has not been intentionally doped.

The charge carrier density of a given layer is readily measurable by the skilled person, for example by capacitance-voltage profiling or calibrated scanning capacitance microscopy. A depth profiling Hall effect technique may also be suitable. The charge carrier density may alternatively be termed the carrier density, or the carrier concentration. References to charge carrier density herein refer to the charge carrier density at room temperature.

The surface layer and/or the first region may be formed by epitaxial growth. The surface layer and/or the first region may be formed by molecular beam epitaxy (MBE), metalorganic chemical vapour deposition (MOCVD) (also known as metalorganic vapour phase epitaxy (MOVPE)), hydride vapour phase epitaxy (HVPE), ammonothermal processes, or other conventional processes suitable for growing III-nitride materials with the necessary charge carrier concentrations.

The surface layer and/or the first region may be grown on an electrically insulating base layer, or substrate. Preferably the base layer is configured to form the bottom of a multi-layer structure, the surface layer forms the top of the multi-layer structure, with the sub surface first region arranged in between the surface layer and the base layer. Preferably the electrically insulating substrate may comprise sapphire, silicon, silicon carbide, LiAlO₃, glass or bulk GaN.

Particularly advantageously, as access to layer edges is not required, the method of the present invention does not require samples to be pre-prepared by creating trenches in the layers. The present invention may thus require fewer processing steps, and allow the porosification of large, continuous, semiconductor layers, without the need to break the layers up with regular trenches.

By controlling the charge carrier density of each region of the semiconductor structure, it is possible to control which regions are porosified by the plasma electrolytic etching process. Thus, a variety of multi-layer structures may be grown, in order to achieve different porosity characteristics in pre-determined regions and/or layers.

The method of the present invention may thus allow selective sub-surface porosification of a plurality of sub-surface first regions based on their charge carrier densities, by etching through the surface layer and any further sub-surface regions with a charge carrier density less than 1×10¹⁷ cm⁻³. Particularly advantageously, the method may porosify those sub surface regions with a charge carrier density greater than 1×10¹⁷ cm⁻³ without damaging, roughening or porosifying those layers with a charge carrier less than 1×10¹⁷ cm⁻³.

As the present method provides plasma electrolytic etching through layers with a charge carrier density of less than 1×10¹⁷ cm⁻³, it is possible to etch pores in a region of the sub-surface structure that is far from any side-wall or edge of the semiconductor structure.

Thus, the present method may advantageously etch a first region of the sub-surface structure that is at least 300 μm, or 500 μm, or 750 μm, or 1 mm, or 1 cm, or 5 cm, away from the nearest side-wall, or edge, of the semiconductor structure. This would not be possible with horizontal electrochemical etching techniques of the prior art, which are limited in the distance that it is possible to etch in from a layer edge, to a few tens, or at most a few hundreds of micrometres.

Particularly preferably, the method is carried out without providing trenches in the surface layer and the sub-surface structure.

Preferably the surface layer is not coated with an electrically insulating layer during electrochemical etching.

Preferably the sample is not illuminated with UV illumination during electrochemical etching.

According to a second aspect of the present invention there is provided a semiconductor structure comprising porous III-nitride material formed by the method described above in relation to the first aspect of the invention.

According to a third aspect of the invention there is provided a template for semiconductor overgrowth, comprising porous III-nitride material formed by the method described above in relation to the first aspect of the invention. Preferably further III-nitride epitaxial layers and device structures may be deposited directly onto the template by techniques such as MBE, MOCVD, or HVPE. Following this overgrowth, high performance optical and electrical devices may be fabricated on the structures. Suitable devices may include, for example, light-emitting diodes (LED), laser diodes (LD), high electron mobility transistors (HEMT), solar cells, and semiconductor-based sensor devices.

According to a fourth aspect of the invention there is provided a semiconductor device comprising porous III-nitride material formed by the method described above in relation to the first aspect of the invention. The semiconductor device may, for example, a light-emitting diode (LED), laser diode (LD), high electron mobility transistor (HEMT), solar cell, or a semiconductor-based sensor device.

### BRIEF DESCRIPTION OF THE DRAWINGS

Specific embodiments of the invention will now be described with reference to the figures, in which:

FIG. 1 shows a schematic illustration of the experimental setup for plasma electrolytic etching;

FIG. 2 shows a schematic illustration of the experimental setup for plasma electrolytic etching, with the polarity of the power source reversed; and

FIG. 3 illustrates an exemplary I-V curve representing the conditions applied between electrodes during plasma electrolytic etching.

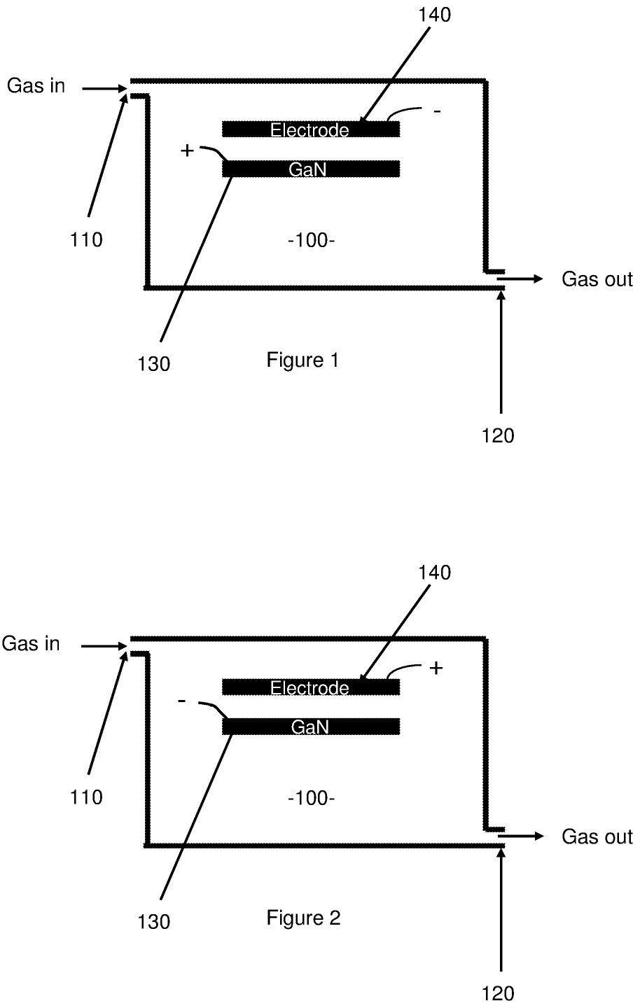

As shown in FIG. 1, a chamber 100 is provided with a gas inlet 110 and a gas outlet 120, so that a gas may be pumped continuously through the chamber using a pump (not shown).

A GaN semiconductor wafer 130 is positioned roughly in the centre of the chamber 100. At least a first region of the semiconductor wafer 130 has an n-doped charge carrier concentration of at least 1×10¹⁷ cm⁻³. The GaN semiconductor wafer 130 is connected to the positive terminal of a variable-voltage power supply (not shown).

Also positioned in the chamber 100 is an electrode 140, which is connected to the negative terminal of the power supply.

When semiconductor wafers to be porosified include an electrically-insulating surface layer covering the first region of doped III-nitride material, the electrically-insulating surface layer is positioned between the first region of III-nitride material and the electrode 140.

The first region of the semiconductor wafer 130 is preferably formed over a substrate, which prevents gas from contacting the underside of the first region.

The gas supply is configured so that the composition of the gas, and the gas pressure, may be adjusted during operation. The temperature of the container is also externally controllable using heating and cooling elements (not shown).

The power supply is controllable to provide voltages of up to 10,000 V, and to vary the voltage between the GaN wafer and the electrode during operation. The power supply is capable of applying constant, pulsed, or swept voltages. The power supply may preferably be an alternating current (AC) power supply.

In use, gas is pumped through the chamber 100 from the inlet 110 to the outlet 120, and a voltage is applied between the GaN wafer 130 and the electrode 140. The voltage applied between the wafer and the electrode creates an electrically conductive gas plasma, through which current can flow between the wafer 130 and the electrode 140.

In an example process according to the present invention, the gas may be a mixture of NH3, CH4 and H2O. In another example process the gas may be air.

Once current is flowing through the plasma, pores are etched selectively in the first region of the GaN wafer 130 by plasma electrolytic etching, so that the first region becomes a porous region of GaN. The mechanism of porosification is thought to be substantially similar to that previously observed in EC etching. However, as there is no need to use liquid electrolyte in the plasma electrolytic etching process of the present invention, the present invention eliminates the requirement for costly, time-consuming and polluting cleaning steps after porosification.

FIG. 2 illustrates the same apparatus as FIG. 1, with the GaN semiconductor wafer 130 and the electrode 140 connected to opposite terminals of the battery. The GaN semiconductor wafer 130 is connected to the negative terminal of a variable-voltage power supply (not shown), and the electrode 140 is connected to the negative terminal of the power supply. The apparatus advantageously works with the semiconductor wafer and the electrode connected to either terminal of the power supply.

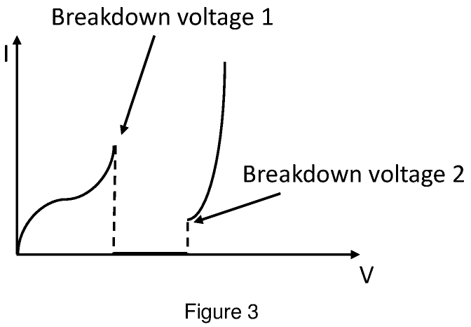

FIG. 3 illustrates the I-V curve for the plasma electrolytic etching of the n-doped GaN wafer 130.

After the circuit is energised at a low voltage, the voltage between the electrode 140 and the semiconductor wafer 130 is gradually ramped up. When the voltage between the electrode 100 and the GaN wafer 130 exceeds the first breakdown voltage, electrically conductive channels form in the GaN wafer. The first breakdown voltage may vary depending on the gas used, but is typically between 100 V and 1 kV, or between 500 V and 5 kV, or between 750 V and 10 kV.

While the voltage is ramped up, the separation between the GaN wafer and the (counter) electrode 140 may be varied, and the pressure and composition of the gas in the chamber 100 may be varied.

The voltage between the electrode 140 and the semiconductor wafer 130 is increased until it exceeds a second breakdown voltage above which pores form in the n-doped regions of the GaN wafer. The second breakdown voltage may typically be between 10 kV and 500 kV, or between 50 kV and 300 kV, or between 75 kV and 200 kV. Typically the second breakdown voltage is greater than 100 kV.

When the voltage between the electrode 140 and the GaN wafer exceeds the second breakdown voltage, the n-doped GaN material in the wafer begins to break down, forming pores in the doped regions of the wafer.

The voltage is maintained above the second breakdown voltage for a desired period to allow the porosification of the n-doped III-nitride material to take place to the desired extent. The voltage across the circuit is then reduced and the circuit is de-energised.

1. A method for forming porous III-nitride material, comprising:
exposing a III-nitride material to a gas;
coupling the III-nitride material to one terminal of a power supply and coupling an electrode to another terminal of the power supply, and via the gas forming a circuit; and
energising the circuit to etch a plurality of pores in the III-nitride material and thereby form a porous III-nitride material.

2. A method according to claim 1, in which energising the circuit creates a gas plasma.

3. A method according to claim 1 or 2, in which the pores are etched in the III-nitride material by plasma electrolytic etching.

4. A method according to any preceding claim, in which the III-nitride material is not exposed to an electrolyte.

5. A method according to any preceding claim, in which the gas is a gas mixture.

6. A method according to any preceding claim, in which the gas comprises H₂, O₂, N₂, Ar, CO₂, CH₄, H₂O, H₂O₂, O₃, CO, SO₂, SO₃, NO₂, NO, H₂S, NH₃, O₁₂, Br₂, F₂, I₂, HCl, HBr, or HF, or a mixture of two or more of H₂, O₂, N₂, Ar, CO₂, CH₄, H₂O, H₂O₂, O₃, CO, SO₂, SO₃, NO₂, NO, H₂S, NH₃, O₁₂, Br₂, F₂, I₂, HCl, HBr, or HF, or in which the gas is air.

7. A method according to any preceding claim, in which the gas comprises a vapour of one or more inorganic salts.

8. A method according to claim 7, in which the gas comprises a vapour of one or more of LiF, NaF, NaCl, LiCl, KCl, LiBr, LiNO₃, NaNO₃, KNO₃, CaCl₂, SnCl₂, ZnCl₂, ZnBr₂, CuCl₂, AlCl₃, FeCl₃, TiCl₄, ZrCl₄, PCl₃, PCl₅, NH₄Cl, NH₄NO₃.

9. A method according to any preceding claim, in which the gas comprises a vapour of one or more metals.

10. A method according to claim 9, in which the gas comprises a vapour of one or more of Li, Na, K, Hg, Ga, In, Al, or Pb.

11. A method according to any preceding claim, in which the gas comprises a vapour of one or more acids, preferably one or more acids of low boiling point, for example boiling points <350° C. at 1 atm.

12. A method according to claim 11, in which the gas comprises a vapour of one or more of formic acid, acetic acid, propionic acid, butyric acid, citric acid, oxalic acid, or HPO₃.

13. A method according to any preceding claim, further comprising the step of varying the composition of the gas.

14. A method according to claim 13, comprising the step of varying the composition of the gas as a function of time to generate a porosity profile.

15. A method according to claim 13, comprising the step of varying the composition of the gas while the circuit is energised, or the steps of de-energising the circuit, altering the composition of the gas, and re-energising the circuit.

16. A method according to any preceding claim, comprising the step of exposing the III-nitride material to a vapour of one or more inorganic salts, and/or a vapour of one or more metals, as a function of time to generate a porosity profile.

17. A method according to any preceding claim, further comprising the step of applying a voltage in the range between 0.1 V and 500,000 V, or between 0.5 V and 250,000 V, or between 1 V and 150,000 V.

18. A method according to any preceding claim, further comprising the step of varying the voltage as a function of time.

19. A method according to any preceding claim, in which the etching comprises applying a first voltage V₁ for a first time duration t_{V1}; and applying a second Voltage V₂ for a second time duration t_{V2}.

20. A method according to any preceding claim, in which the voltage is swept between a first voltage V₁ and a second Voltage V₂ over a predetermined period of time.

21. A method according to any preceding claim, in which the amplitude of the voltage increases from about 1 volt to a maximum of up to 500,000 volts over the predetermined period of time, preferably from about 1 volt to a maximum of up to 250,000 volts or from about 1 volt to a maximum of up to 150,000 volts or 100,000 volts.

22. A method according to any preceding claim, further comprising the step of applying a sequence of voltage pulses, optionally a sequence of voltage pulses of alternating polarity, for a predetermined period of time.

23. A method according to claim 22 in which the voltage pulses have a pulse repetition frequency of between 0.1 and 20 KHz, preferably between 1.5 and 15, or between 2 and 10 KHz.

24. A method according to any preceding claim, wherein the III-nitride material is coupled to the either negative or positive terminal of the power supply.

25. A method according to any preceding claim, comprising the step of varying the pressure of the gas while the circuit is energised.

26. A method according to claim 25, comprising the step of sweeping the pressure of the gas between 0 bar and 20 bar, or between 1 bar and 15 bar, or between 1 bar and 10 bar, while the circuit is energised.

27. A method according to claim 25, comprising the step of applying a first gas pressure P₁ for a first time duration t_{P1}; and applying a second gas pressure P₂ for a second time duration t_{P2}.

28. A method according to any preceding claim, further comprising the step of varying a temperature of the gas and the III-nitride material, preferably while the circuit is energised.

29. A method according to claim 28, comprising the step of applying a first gas temperature T₁ for a first time duration t_{P1}; and applying a second gas temperature T₂ for a second time duration T_{P2}.

30. A method according to any preceding claim, in which the temperature of the gas is swept between a first temperature T₁ and a second temperature T₂ over a predetermined period of time.

31. A method according to any of claims 28 to 30, comprising the step of exposing the III-nitride material to the gas at a temperature in the range between −50° C. and 1100° C., or between 0° C. and 1000° C., or between 50° C. and 800° C., or between 100° C. and 500° C.

32. A method according to any of claims 28 to 31, comprising the step of varying a temperature of the gas and the III-nitride material between a first temperature T₁ and a second temperature T₂ while the circuit is energised.

33. A method according to any preceding claim, further comprising the step of varying a distance between the electrode and the III-nitride material, preferably while the circuit is energised.

34. A method according to any preceding claim, comprising the steps of forming a non uniform porosity profile in the III-nitride material by varying one or more of: the gas composition; the voltage applied between the electrode and the III-nitride material; the distance between the electrode and the III-nitride material; the temperature of the gas; and the pressure of the gas.

35. A method according to any preceding claim, in which the III-nitride material has a charge carrier density of greater than 1×10¹⁷ cm⁻³.

36. A method according to any preceding claim, in which at least a first region of the III-nitride material consists of n-type doped III-nitride material, which is preferably doped with one or more of silicon (Si), germanium (Ge) and oxygen (O).

37. A method according to any preceding claim in which the plurality of pores are etched in a first region of the III-nitride material, and in which the first region of III-nitride material has a charge carrier density of greater than 1×10¹⁷ cm⁻³.

38. A method according to claim 35 or 36, in which the III-nitride material additionally comprises a second portion having a charge carrier density of less than 1×10¹⁷ cm⁻³, and in which no pores are formed in the second portion.

39. A method according to any preceding claim, in which the III-nitride material is a first region of III-nitride material, and in which an undoped surface layer of III-nitride material is positioned over the first region of III-nitride material

40. A method according to any preceding claim, further comprising forming over the porous III-nitride material:
an n-type layer,
a p-type layer, and
InGaN/GaN active layers between the n-type layer and the p-type layer to form a light emitting diode (LED).

41. A method according to any preceding claim, wherein the III-nitride material is disposed on a substrate comprising Sapphire, silicon, silicon carbide, or bulk GaN.

42. A method according to any preceding claim, in which the III-nitride material is selected from the list consisting of: GaN, AlGaN, InGaN, InAlN and AlInGaN.

43. A method according to any preceding claim, in which the III-nitride material is provided as a wafer with a diameter of 1 inch (2.54 cm), or 2 inches (5.08 cm), or 6 inches (15.24 cm), or 8 inches (20.36 cm), or 16 inches or larger.

44. A semiconductor structure comprising porous III-nitride material formed by a method defined in any preceding claim.

45. A template for semiconductor overgrowth, comprising porous III-nitride material formed by a method defined in any of claims 1 to 43.

46. A semiconductor device comprising porous III-nitride material formed by a method defined in any of claims 1 to 43.
